(19) United States
(12) Patent Application Publication
(10) Pub. No.: US 2015/0028922 A1
(43) Pub. Date: Jan. 29, 2015

(54) TRANSISTOR SWITCH WITH TEMPERATURE COMPENSATED VGS CLAMP

(71) Applicant: Texas Instruments Incorporated, Dallas, TX (US)

(72) Inventors: Richard Turkson, Richardson, TX (US); Aline C. Sadate, Allen, TX (US); Philomena C. Brady, Corinth, TX (US)

(21) Appl. No.: 14/289,468

(22) Filed: May 28, 2014

Related U.S. Application Data
(60) Provisional application No. 61/885,109, filed on Oct. 1, 2013.
(60) Provisional application No. 61/828,588, filed on May 29, 2013.

(51) Int. Cl. H03K 17/14

(52) U.S. Cl. CPC H03K 17/145
USPC 327/109

(57) ABSTRACT

A methodology for controlling FET switch-on with V_{GS} temperature compensation is based on establishing a V_{GS} clamping voltage with PTAT and CTAT voltage references with complimentary temperature coefficients. In one embodiment, the methodology can include: (a) generating a PTAT current from a PTAT ΔV_{BE} current source including a ΔV_{BE} resistor; (b) supplying the PTAT current to the gate node to control FET switch-on; and (c) establishing a temperature compensated V_{GS} clamping voltage at the gate node. The V_{GS} clamping voltage can be established with gate control circuitry that includes the PTAT and CTAT voltage references. A PTAT voltage V_{PTAT} is dropped across a PTAT resistor R_{PTAT} characterized by a temperature coefficient substantially the same as the ΔV_{BE} resistor. The CTAT voltage V_{CTAT} is dropped across one or more CTAT V_{BE} component(s) each characterized by a V_{BE,CTAT} voltage drop with a CTAT temperature coefficient. As a result, the (positive) temperature dependence of the V_{PTAT} voltage reference is compensated by the (negative) temperature dependence of the V_{CTAT} voltage reference.

### CROSS-REFERENCE TO RELATED APPLICATIONS

Priority is hereby claimed under USC §119(e) to: (a) U.S. Provisional Application 61/828,588 (Texas Instruments docket TI-73746PS, filed May 29, 2013), and (b) U.S. Provisional Application 61/885,109 (Texas Instruments docket TI-73746P, filed Oct. 1, 2013).

### BACKGROUND

1. Technical Field

This Patent Document relates generally to transistor switch control, and more particularly, control for MOSFET switch-on, such as can be used in load switching applications.

2. Related Art

Load switches are examples of transistor switches that require control networks to control switch-on/off. For load switch applications, the load switch is controlled to connect/disconnect a power source (such as a battery) and a load, passing voltage and current to the load without, for example, performing current limiting or other power switch control functions. Instead, load switch control networks are employed to control various switch-on/off parameters such as turn-on delay and slew rate (for example, to control inrush current).

A high-side switch connects the load to the power source, sourcing current to the load. A low-side switch connects the load (which is connected to the power source) to ground, sinking current from the load. MOSFET transistors have a number of advantages for load switching applications, including low switch-on current consumption, low switch-off leakage current, and good thermal stability.

Referring to FIG. 1, a load switch 10 includes an NFET high-side switch with a gate node N1. A gate control block 11 is coupled to gate node N1. A current source 13 supplies current to charge the control gate to V_{BIAS}. To prevent damage to the FET gate oxide, a stack of diodes 15 is connected between the FET gate and source to clamp the gate source voltage V_{GS}.

A disadvantage of the diode stack, particularly for low voltage load switching applications, is the dependence of the diode stack on temperature, which inhibits optimizing an important design parameter, transistor on-resistance R_{ON}. R_{ON} is dependent on V_{GS} (FIG. 2A), so that to optimize R_{ON}, the maximum V_{GS} allowed by the MOSFET process is the design goal. However the diode clamp exhibits a significant negative temperature coefficient, making the V_{GS} clamping voltage temperature dependent, which makes V_{GS} temperature dependent (FIG. 2B).

One approach to providing a temperature compensated V_{GS} clamp is to include a zener diode with a positive temperature coefficient in series with the diode stack (with a negative temperature coefficient). This approach is disadvantageous for low voltage applications, where V_{GS} is below the zener break down voltage (greater than 6V).

While this Background information is presented in the context of load switching applications, the present Disclosure is not limited to such applications, but is more generally directed to transistor switching control.

### BRIEF SUMMARY

This Brief Summary is provided as a general introduction to the Disclosure provided by the Detailed Description and Figures, summarizing some aspects of the disclosed invention. It is not a detailed overview of the Disclosure, and should not be interpreted as identifying key elements of the invention, or otherwise characterizing the scope of the invention(s) disclosed in this Patent Document.

The Disclosure describes apparatus and methods for controlling FET switch-on with V_{GS} temperature compensation, such as can be used in load switching applications.

In one embodiment, the methodology for controlling FET switch-on with V_{GS} temperature compensation, according to aspects of the invention can include: (a) generating a PTAT current I_{PTAT} from a PTAT ΔV_{BE} current source including a ΔV_{BE} resistor, I_{PTAT} corresponding to a voltage across the ΔV_{BE} resistor; (b) supplying the I_{PTAT} current to the gate node to control FET switch-on, including charging the FET gate; and (c) establishing a temperature compensated V_{GS} clamping voltage V_{GS,Clamp} at the gate node.

The temperature compensated V_{GS} clamping voltage V_{GS,Clamp} is established with gate control circuitry that includes (i) a PTAT resistor R_{PTAT}, characterized by a temperature coefficient substantially the same as the ΔV_{BE} resistor, coupled to the gate node such that a PTAT voltage [V_{PTAT}=(R_{PTAT}*I_{PTAT})] is developed across R_{PTAT}, and (ii) at least one CTAT V_{BE} component, characterized by a V_{BE,CTAT} voltage drop with a CTAT temperature coefficient, coupled between R_{PTAT} and the FET source such that a CTAT voltage [V_{CTAT}=V_{BE,CTAT}] is developed across the CTAT V_{BE} component.

As a result, (i) the temperature dependence of [V_{PTAT}=(R_{PTAT}*I_{PTAT})] is compensated by the temperature dependence of [V_{CTAT}=V_{BE,CTAT}], and (ii) the V_{GS} clamping voltage at the gate node corresponds to [V_{GS,Clamp}=V_{PTAT}+V_{CTAT}=(R*I_{PTAT})+V_{BE,CTAT}].

In other embodiments, the methodology for controlling FET switch-on with V_{GS} temperature compensation can include: (a) establishing the voltage [(R*I+PTAT)+V_{BE,CTAT}] corresponds to V_{GS,MAX}, such that the FET gate-source voltage is clamped to a voltage corresponding to [V_{GS,Clamp}=V_{GS,MAX}]; (b) establishing a CTAT voltage with n CTAT V_{BE} diode-connected bipolar transistors, such [V_{CTAT}=nV_{BE,CTAT}]; (c) implementing the PTAT ΔV_{BE} current source with bipolar transistors Q1 and Q2 configured as a ΔV_{BE} circuit, including the ΔV_{BE} resistor; and current mirror circuitry coupled to the ΔV_{BE} circuit, and configured to supply the PTAT current I_{PTAT}; and (d) adapting the methodology for an NFET high side load switch.

Other aspects and features of the invention claimed in this Patent Document will be apparent to those skilled in the art from the following Disclosure.

### BRIEF DESCRIPTION OF THE DRAWINGS

FIG. 1 illustrate an existing load switch, including a gate control block with a V_{GS} clamp implemented as a diode stack.

FIGS. 2A and 2B are plots illustrating, for the load switch of FIG. 1 with a V_{GS} diode clamp, respectively: (2A) the relationship of V_{GS} and temperature, and (2B) the relationship of R_{ON} and V_{GS}.

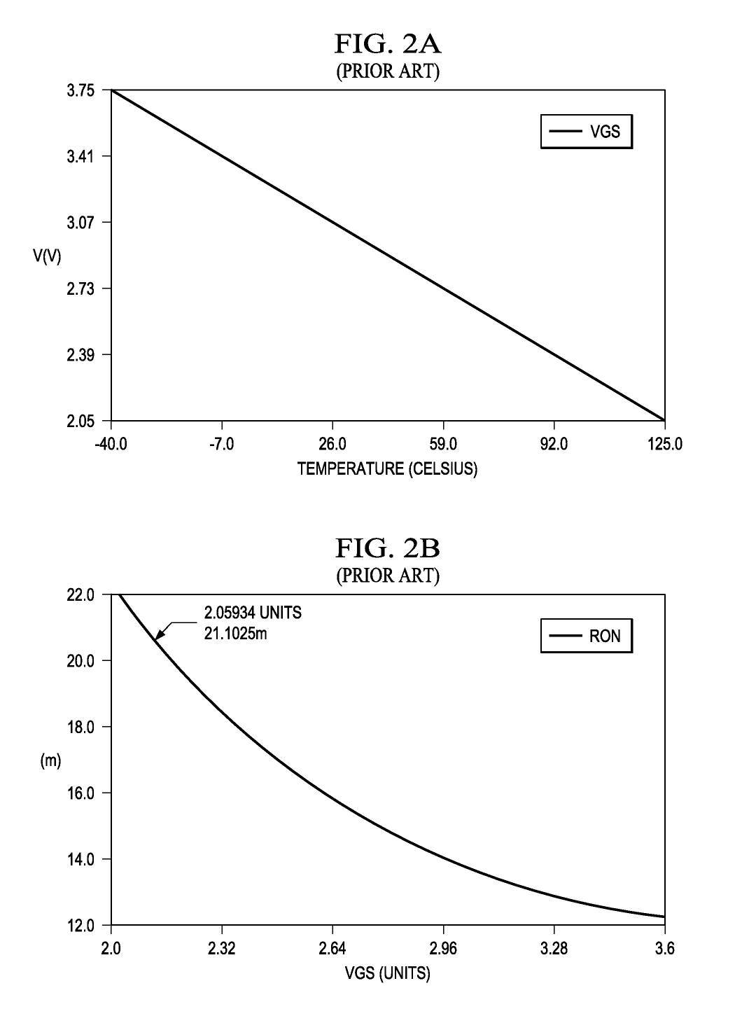

FIG. 3 illustrates an example embodiment of transistor switch including gate control with a temperature compensated V_{GS} clamp according to the invention, configured as an NFET high-side load switch, with a gate control block that includes a PTAT ΔV_{BE} current source providing to the gate node a PTAT current I_{PTAT}, and a VGS clamping circuit including a PTAT resistor R_{PTAT}, and a CTAT nV_{BE} stack, providing a temperature compensated VGS clamp voltage V_{GS,Clamp} based on PTAT and CTAT voltage references [V_{PTAT}+V_{CTAT}=(R_{PTAT}*I_{PTAT})+nV_{BE,CTAT}].

FIGS. 4A and 4B are plots illustrating, for the example embodiment of a load switch in FIG. 3, V_{GS} and R_{ON} temperature compensation according to the invention: (4A) illustrates compensated V_{GS} versus temperature [V 3.41-3.45; T(c) −50-125]; and (4B) illustrates the compensated R_{ON,Comp} versus temperature [m 7.5-22.5; T(c) −50-125], in comparison to R_{ON} variation for a conventional diode stack V_{GS} clamp such as illustrated in FIG. 1.

FIG. 5 illustrates an example system 200 in which load switches can be implemented based on the methodology for controlling FET switch-on with V_{GS} temperature compensation by establishing a V_{GS} clamping voltage with PTAT and CTAT voltage references with complimentary temperature coefficients.

### DETAILED DESCRIPTION

This Description and the Figures disclose example embodiments and applications that illustrate various features and advantages of the invention, aspects of which are defined by the Claims. Known circuits, functions and operations are not described in detail to avoid unnecessarily obscuring the principles and features of the invention.

In brief overview, the methodology for controlling FET switch-on with V_{GS} temperature compensation is based on establishing a V_{GS} clamping voltage with PTAT and CTAT voltage references with complimentary temperature coefficients. An FET gate control block includes a PTAT ΔV_{BE} current source, and a V_{GS} clamp circuit, coupled at a gate node to the FET. The PTAT ΔV_{BE} current source (including a ΔV_{BE} resistor) supplies an I_{PTAT} current to the gate node, i.e. to the V_{GS} clamp. The V_{GS} clamp includes a PTAT resistor R_{PTAT} in series with some number n of CTAT VBE components (for example, diode-connected transistors), each characterized by a V_{BE,CTAT} voltage drop with a CTAT temperature coefficient (n is one or more). The V_{GS} clamp voltage at the gate node is V_{GS,Clamp}=V_{PTAT}+V_{CTAT}=[R_{PTAT}*I_{PTAT}]+[nV_{BE,CTAT}]. As a result, the (positive) temperature dependence of [V_{PTAT}=(R_{PTAT}*I_{PTAT})] compensates the (negative) temperature dependence of [V_{CTAT}=nV_{BE,CTAT}], thereby reducing the temperature dependence of the V_{GS} clamping voltage in relation to V_{GS,MAX}, and thereby reducing the temperature dependence of FET R_{ON}.

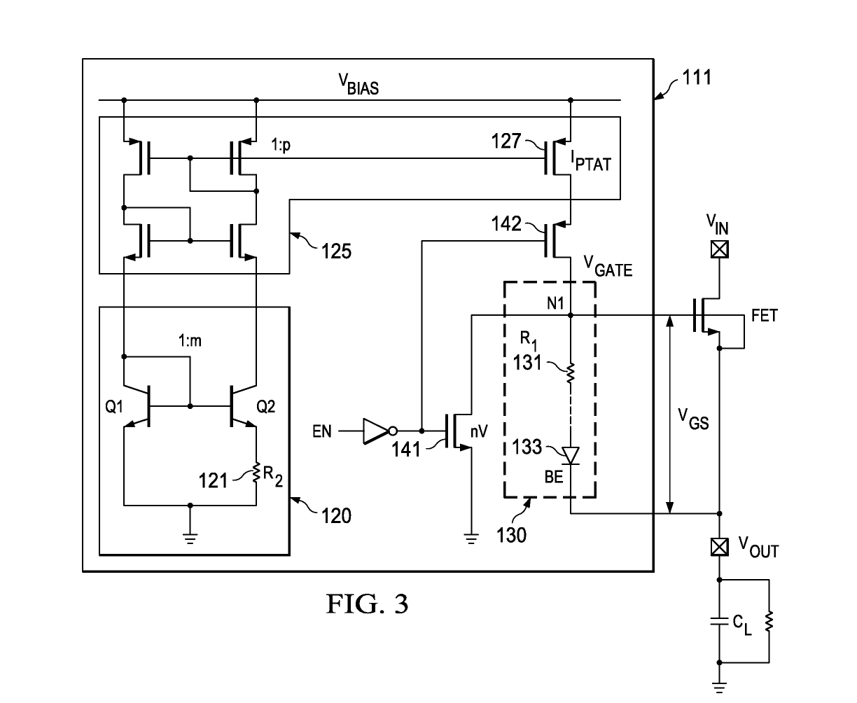

FIG. 3 illustrates an example embodiment of a transistor switch including gate control with a temperature compensated V_{GS} clamp according to the invention, adapted as a load switch 100 with a high-side NFET characterized by a gate-source voltage V_{GS} with a maximum rated value of V_{GS,MAX}. The NFET is coupled between a power source represented by VIN and a load represented by V_{OUT}.

The methodology for controlling FET switch-on with a temperature compensated V_{GS} clamp, illustrated for a load switch with a high side NFET, is adaptable to transistor switch control applications other than load switching, and for use with PFET low-side transistor switches. Selecting NFET versus PFET implementations represents known design trade-offs, for example, lower R_{ON} versus complexity/size considerations in introducing a separate supply (V_{BIAS}), and input voltage required to be passed on to the load.

Load switch 100 includes a gate control block 111 coupled between a gate node N1 and the FET source, and is configured to provide V_{GS} temperature compensation according to the invention. V_{GS} temperature compensation is based on establishing a V_{GS} clamping voltage with PTAT and CTAT voltage references with complimentary temperature coefficients.

Gate control block 111 is configured to control NFET VGS during NFET switch-on, including charging the NFET gate. The gate control block includes a PTAT ΔV_{BE} current source 120,125, and a V_{GS} clamping circuit 130.

For the illustrated example embodiment, the PTAT ΔV_{BE} current source 120,125 is implemented with a ΔV_{BE} circuit 120 including a ΔV_{BE} resistor 121, and a current mirror 125. During FET switch-on, the PTAT ΔV_{BE} current source is configured to supply to gate node N1 a PTAT current I_{PTAT} corresponding to a voltage across the ΔV_{BE} resistor 121.

The ΔV_{BE} circuit 120 is implemented with matched transistors Q1-Q2 with different current densities (for example, 1:8), producing a ΔV_{BE} across the ΔV_{BE} resistor 121. The current mirror 125 is implemented with MOSFETs, including a PFET 127 supplying the PTAT current I_{PTAT} to gate node N1 (through an enable transistor 142 described below). PTAT ΔV_{BE} current source 120,125 is biased by V_{BIAS} (as is conventional for high-side NFET load switches).

V_{GS} clamping circuit 130 is coupled between gate node N1 and the NFET source, and is configured to establish a temperature compensated V_{GS} clamping voltage V_{GS,Clamp} at the gate node, according to the invention. The VGS clamp 130 includes PTAT and CTAT voltage references V_{PTAT} and C_{PTAT} with respective temperature coefficients of opposite polarity.

The PTAT voltage reference V_{PTAT} is provided by a PTAT resistor R_{PTAT} 131 characterized by a temperature coefficient substantially the same as the ΔV_{BE} resistor 121. PTAT resistor R_{PTAT} 131 is coupled to gate node N1 such that the PTAT voltage V_{PTAT} is dropped across R_{PTAT} based on the PTAT current I_{PTAT} into gate node N1, i.e. [V_{PTAT}=(R_{PTAT}*I_{PTAT})]. That is, the ΔV_{BE} resistor 121 and the PTAT resistor R_{PTAT} 131 should be matched to cancel out related temperature coefficients.

The CTAT voltage reference V_{CTAT} is implemented with one or more CTAT V_{BE} components, characterized by a V_{BE,CTAT} voltage drop with a negative CTAT temperature coefficient that compensates for the positive PTAT temperature coefficient of the PTAT voltage reference V_{PTAT}[(R_{PTAT}*I_{PTAT})]. The CTAT nV_{BE} component(s) (where n is one or more) is coupled between R_{PTAT} and the FET source, such that the CTAT voltage V_{CTAT} is dropped across the CTAT nV_{BE} component(s), i.e. [V_{CTAT}=nV_{BE,CTAT}].

The illustrated CTAT V_{BE} component can be implemented as a diode-connected transistor (commonly, a bipolar transistor), or a stack of n diode-connected transistors providing the [V_{CTAT}=nV_{BE,CTAT}].

According to the invention, the temperature dependence (positive) of the PTAT voltage reference [V_{PTAT}=(R_{PTAT}*I_{PTAT})] is compensated by the temperature dependence (negative) of the CTAT voltage reference [V_{CTAT}=nV_{BE,CTAT}]. As a result, the temperature compensated V_{GS} clamping voltage V_{GS,Clamp} at gate node N1 corresponds to [V_{PTAT}+V_{CTAT}=(R_{PTAT}*I_{PTAT})+nV_{BE,CTAT}].

Thus, to optimize R_{ON} across temperature, the gate control block 111, including the V_{GS} clamp circuit 130. can be configured to maximize V_{GS} (minimizing R_{ON}), by reducing V_{GS} temperature dependence, i.e., the V_{GS,Clamp} voltage [(R_{PTAT}*I_{PTAT})+nV_{BE,CTAT}] can be configured for V_{GS,MAX} across temperature.

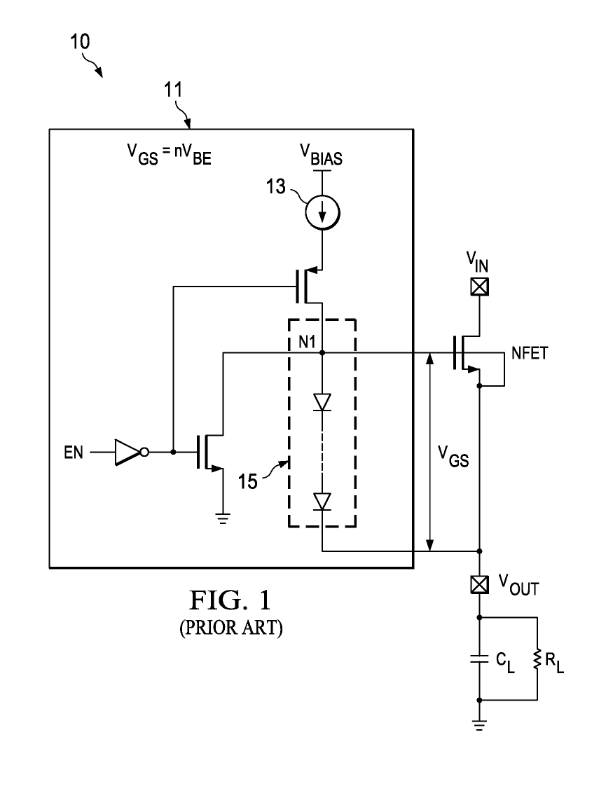

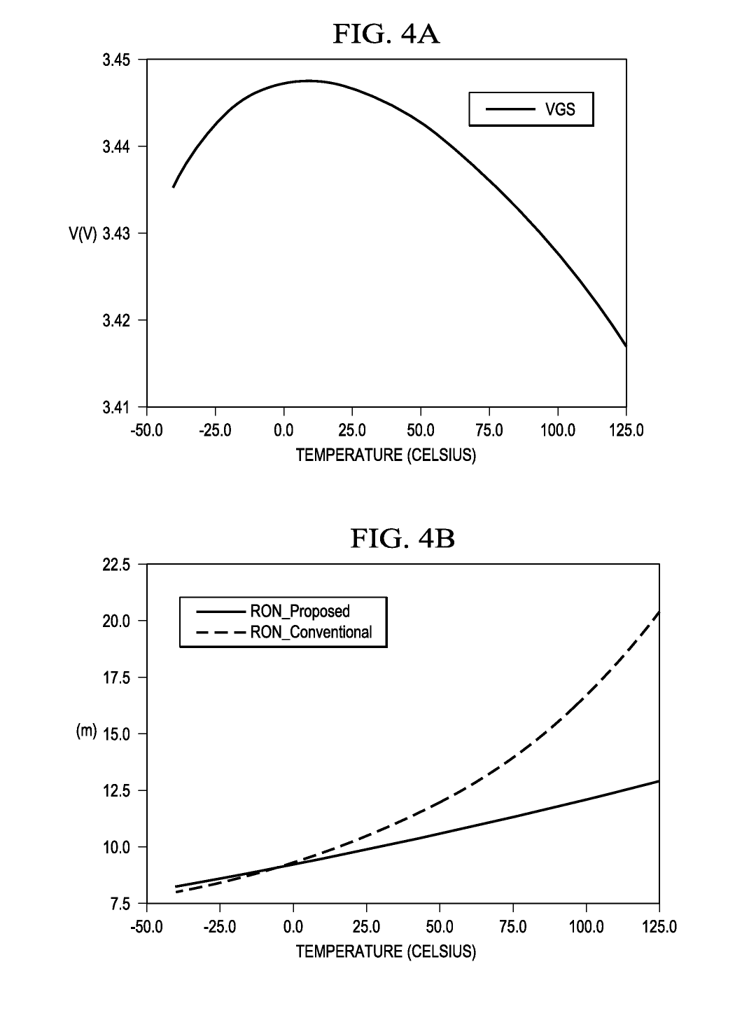

FIGS. 4A and 4B are plots illustrating, for the example embodiment of a load switch in FIG. 3, V_{GS} and R_{ON} temperature compensation according to the invention. FIG. 4A illustrates compensated V_{GS} versus temperature, and FIG. 4B illustrates compensated R_{ON,Comp} versus temperature, in comparison to an R_{ON} variation for a conventional diode stack V_{GS} clamp such as illustrated in FIG. 1.

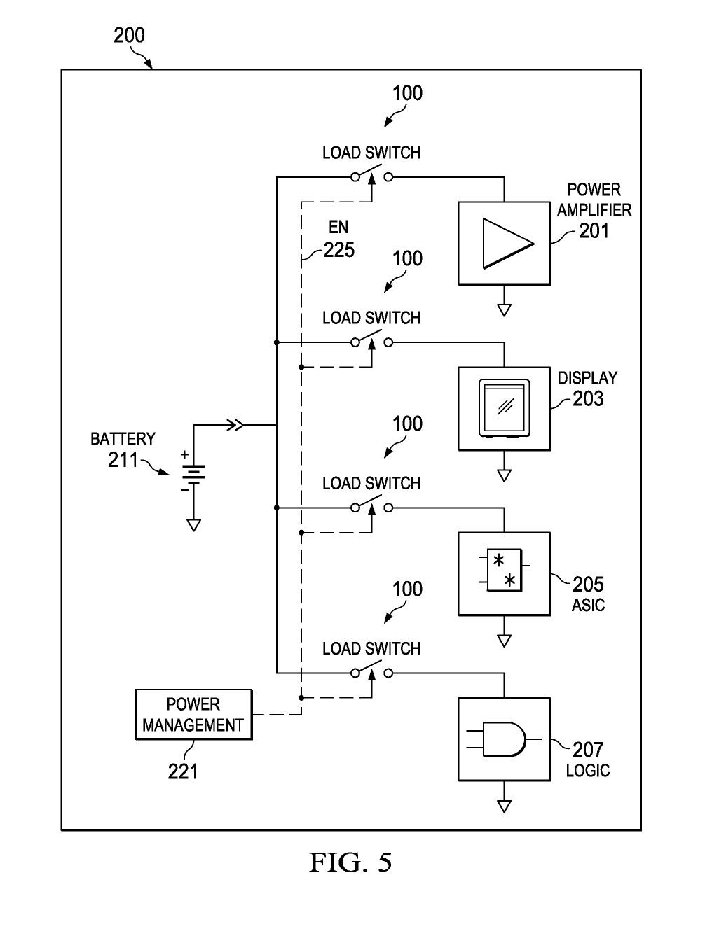

FIG. 5 illustrates an example system 200 in which load switching can be implemented according to the invention. System 200 includes a multiple load subsystems, such as power amplifier 201, Display 203, ASIC 205 and Logic 207. The load subsystems receive power from a power source, such as battery 211, which each load subsystem coupled to batter 211 by a load switch 100, configures according to aspects of the invention. A power management unit 221 controls each load switch 100, connecting/disconnecting the power source and respective subsystem loads 201-207.

In response to an enable signal EN from power management unit 221, a selected load switch 100 switches on. Referring back to FIG. 3, for the illustrated load switch, gate control block 111 includes switch enable circuitry that switches-on the NFET switch in response to an enable signal EN, supplying a switch-on signal to the NFET gate. The switch enable circuit includes switches 141 and 142, both connected to gate node N1. When the switch enable signal EN is asserted, switch 141 provides a switch-on signal to the NFET gate (through gate node 1). Switch 142 connects the PTAT ΔV_{BE} current source 120,125 to gate node N1, supplying the PTAT current I_{PTAT} to the gate node, and to the V_{GS} clamp 130.

The Disclosure provided by this Description and the Figures sets forth example embodiments and applications, including associated operations and methods, that illustrate various aspects and features of the invention. These example embodiments and applications may be used by those skilled in the art as a basis for design modifications, substitutions and alternatives to construct other embodiments, including adaptations for other applications, Accordingly, this Description does not limit the scope of the invention, which is defined by the Claims.

1. An FET switch circuit with V_{GS} temperature compensation, comprising an FET switch including a gate with a gate node and a source, and characterized by a gate-source voltage V_{GS} with a maximum rated value of V_{GS,MAX};
switch enable circuitry configured to switch-on the FET switch by supplying a switch-on signal to the FET gate;
gate control circuitry coupled between the FET gate node and the FET source, and configured to control FET V_{GS} during FET switch-on, including charging the FET gate, the gate control circuitry including:
PTAT ΔV_{BE} current source circuitry including a ΔV_{BE} resistor, and configured to supply to the gate node a PTAT current I_{PTAT} corresponding to a voltage across the ΔV_{BE} resistor;
V_{GS} clamping circuitry coupled between the gate node and the FET source, and configured to establish a temperature compensated V_{GS} clamping voltage V_{GS,Clamp} at the gate node, the V_{GS} clamping circuitry including
a PTAT resistor R_{PTAT}, characterized by a temperature coefficient substantially the same as the ΔV_{BE} resistor, coupled to the gate node such that a PTAT voltage [V_{PTAT}=(R_{PTAT}*I_{PTAT})] is developed across R_{PTAT};
at least one CTAT V_{BE} component, characterized by a V_{BE,CTAT} voltage drop with a CTAT temperature coefficient, coupled between R_{PTAT} and the FET source such that a CTAT voltage [V_{CTAT}=V_{BE,CTAT}] is developed across the CTAT V_{BE} component;
such that (i) the temperature dependence of [V_{PTAT}=(R_{PTAT}*I_{PTAT})] is compensated by the temperature dependence of [V_{CTAT}=V_{BE,CTAT}], and (ii) the V_{GS} clamping voltage at the gate node corresponds to [V_{GS,Clamp}=V_{PTAT}+V_{CTAT}=(R_{PTAT}*I_{PTAT})+V_{BE,CTAT}].

2. The circuit of claim 1, wherein the voltage [(R_{PTAT}*I_{PTAT})+V_{BE,CTAT}] corresponds to V_{GS,MAX}, such that the FET gate-source voltage is clamped to a voltage corresponding to [V_{GS,Clamp}=V_{GS,MAX}].

3. The circuit of claim 1, wherein the at least one CTAT V_{BE} component comprises a plurality n CTAT V_{BE} diode-connected bipolar transistors, such [V_{CTAT}=nV_{BE,CTAT}].

4. The circuit of claim 1, wherein the PTAT ΔV_{BE} current source comprises
bipolar transistors Q1 and Q2 configured as a ΔV_{BE} circuit, including the ΔV_{BE} resistor; and
current mirror circuitry coupled to the ΔV_{BE} circuit, and configured to supply the PTAT current I_{PTAT}.

5. The circuit of claim 4, wherein the current mirror circuitry comprises FET transistors.

6. The circuit of claim 1, wherein the FET switch circuit is configured as load switch coupling a source of input power to a load, and:
wherein the FET is an NFET configured as a high side load switch, with an FET drain configured to couple to the source of input power, and with the FET source configured to couple to the load; and
wherein the gate control circuitry is configured to couple to a source of bias voltage separate from the source of input power.

7. The circuit of claim 1, wherein the switch enable circuitry includes:
a first transistor switch coupled to the gate node supply the switch-on signal to the FET gate; and
a second transistor switch coupled to control the supply of the PTAT current I_{PTAT} to the gate node in response to the supply of the switch-on signal to the FET gate.

8. A load switch circuit for switching power from a power source to a load, comprising
an FET load switch configured to control switching power from the power source to the load, the FET load switch including a gate with a gate node, and characterized by a gate-source voltage V_{GS} with a maximum rated value of V_{GS,MAX};
switch enable circuitry configured to switch-on the FET switch by supplying a switch-on signal to the FET gate
gate control circuitry coupled between the FET gate node and the FET source, and configured to control FET V_{GS} during FET switch-on, including charging the FET gate, the gate control circuitry including:
PTAT ΔV_{BE} current source circuitry including a ΔV_{BE} resistor, and configured to supply to the gate node a PTAT current I_{PTAT} corresponding to a voltage across the ΔV_{BE} resistor;
V_{GS} clamping circuitry coupled between the gate node and the FET source, and configured to establish a temperature compensated V_{GS} clamping voltage V_{GS,Clamp} at the gate node, the V_{GS} clamping circuitry including
a PTAT resistor R_{PTAT}, characterized by a temperature coefficient substantially the same as the ΔV_{BE} resistor, coupled to the gate node such that a PTAT voltage [V_{PTAT}=(R_{PTAT}*I_{PTAT})] is developed across R_{PTAT};
at least one CTAT V_{BE} component, characterized by a V_{BE,CTAT} voltage drop with a CTAT temperature coefficient, coupled between R_{PTAT} and the FET source such that a CTAT voltage [V_{CTAT}=V_{BE,CTAT}] is developed across the CTAT V_{BE} component;
such that (i) the temperature dependence of [V_{PTAT}=(R_{PTAT}*I_{PTAT})] is compensated by the temperature dependence of [V_{CTAT}=V_{BE,CTAT}], and (ii) the V_{GS} clamping voltage at the gate node corresponds to [V_{GS,Clamp}=V_{PTAT}+V_{CTAT}=(R_{PTAT}*I_{PTAT})+V_{BE,CTAT}].

9. The load switch of claim 8, wherein the voltage [(R_{PTAT}*I_{PTAT})+V_{BE,CTAT}] corresponds to V_{GS,MAX}, such that the FET gate-source voltage is clamped to a voltage corresponding to [V_{GS,Clamp}=V_{GS,MAX}].

10. The load switch of claim 8, wherein the at least one CTAT V_{BE} component comprises a plurality n CTAT V_{BE} diode-connected bipolar transistors, such [V_{CTAT}=nV_{BE,CTAT}].

11. The load switch circuit of claim 8, wherein the PTAT ΔV_{BE} current source comprises
bipolar transistors Q1 and Q2 configured as a ΔV_{BE} circuit, including the ΔV_{BE} resistor; and
current mirror circuitry coupled to the ΔV_{BE} circuit, and configured to supply the PTAT current I_{PTAT}.

12. The load switch circuit of claim 11, wherein the current mirror circuitry comprises FET transistors.

13. The load switch circuit of claim 8:
wherein the FET load switch is an NFET configured as a high side load switch, with an FET drain configured to couple to the power source, and with the FET source configured to couple to the load; and
wherein the gate control circuitry is configured to couple to a source of bias voltage separate from the source of input power.

14. The load switch circuit of claim 8, wherein the switch enable circuitry includes:
a first transistor switch coupled to the gate node supply the switch-on signal to the FET gate; and
a second transistor switch coupled to control the supply of the PTAT current I_{PTAT} to the gate node in response to the supply of the switch-on signal to the FET gate.

15. A method of controlling FET switch-on with V_{GS} temperature compensation, the FET switch including a gate with a gate node, and characterized by a gate-source voltage V_{GS} with a maximum rated value of V_{GS,MAX}, comprising, during FET switch-on:
generating a PTAT current I_{PTAT} from a PTAT ΔV_{BE} current source including a ΔV_{BE} resistor, I_{PTAT} corresponding to a voltage across the ΔV_{BE} resistor;
supplying the I_{PTAT} current to the gate node to control FET switch-on, including charging the FET gate; and
establishing a temperature compensated V_{GS} clamping voltage V_{GS,Clamp} at the gate node with gate control circuitry that includes;
a PTAT resistor R_{PTAT,} characterized by a temperature coefficient substantially the same as the ΔV_{BE} resistor, coupled to the gate node such that a PTAT voltage [V_{PTAT}=(R_{PTAT}*I_{PTAT})] is developed across R_{PTAT};
at least one CTAT V_{BE} component, characterized by a V_{BE,CTAT} voltage drop with a CTAT temperature coefficient, coupled between R_{PTAT} and the FET source such that a CTAT voltage [V_{CTAT}=V_{BE,CTAT}] is developed across the CTAT V_{BE} component;
such that (i) the temperature dependence of [V_{PTAT}=(R_{PTAT}*I_{PTAT})] is compensated by the temperature dependence of [V_{CTAT}=V_{BE,CTAT}], and (ii) the V_{GS} clamping voltage at the gate node corresponds to [V_{GS,Clamp}=V_{PTAT}+V_{CTAT}=(R_{PTAT}*I_{PTAT})+V_{BE,CTAT}].

16. The method of claim 15, wherein the voltage [(R_{PTAT}*I_{PTAT})+V_{BE,CTAT}] corresponds to V_{GS,MAX,} such that the FET gate-source voltage is clamped to a voltage corresponding to [V_{GS,Clamp}=V_{GS,MAX}].

17. The method of claim 15, wherein the at least one CTAT V_{BE} component comprises a plurality n CTAT V_{BE} diode-connected bipolar transistors, such [V_{CTAT}=nV_{BE,CTAT}].

18. The method of claim 15, wherein the PTAT ΔV_{BE} current source comprises
bipolar transistors Q1 and Q2 configured as a ΔV_{BE} circuit, including the ΔV_{BE} resistor; and
current mirror circuitry coupled to the ΔV_{BE} circuit, and configured to supply the PTAT current I_{PTAT}.

19. The method of claim 15:
wherein the FET switch is an NFET configured as a high side load switch, with an FET drain configured to couple to the source of input power, and with the FET source configured to couple to the load; and
wherein the gate control circuitry is configured to couple to a source of bias voltage separate from the source of input power.

20. The method of claim 15, wherein FET switch-on is accomplished by:
supplying an FET switch-on signal to the FET gate to switch on the FET switch; and
enabling the supply of the PTAT current I_{PTAT} to the gate node in response to the supply of the switch-on signal to the FET gate.
